(19) United States
(12) Patent Application Publication
(10) Pub. No.: US 2025/0331099 A1
(43) Pub. Date: Oct. 23, 2025

(54) MULTILAYER SUBSTRATE AND WIRING SUBSTRATE

(71) Applicant: Murata Manufacturing Co., Ltd., Nagaokakyo-shi (JP)

(72) Inventors: Kosuke NISHIO, Nagaokakyo-shi (JP); Jumpei TAKABAYASHI, Nagaokakyo-shi (JP)

(21) Appl. No.: 19/254,036

(22) Filed: Jun. 30, 2025

Related U.S. Application Data
(63) Continuation of application No. PCT/JP2023/043757, filed on Dec. 7, 2023.

(30) Foreign Application Priority Data
Jan. 5, 2023 (JP) 2023-000530

(51) Int. Cl. H05K 1/02

(52) U.S. Cl. CPC H05K 1/0242; H05K 1/0243; H05K 2201/09254; H05K 2201/10098

(57) ABSTRACT

A multilayer substrate includes a multilayer body including insulator layers laminated along a Z-axis. A first radiating conductor layer receives or radiates first and second high frequency signals. Vibration directions of electromagnetic fields by the first and second high frequency signals propagating through air are different from each other. A second radiating conductor layer is positioned on a negative side of the Z-axis of the first radiating conductor layer, and overlaps with the first radiating conductor layer. First and second signal paths are connected to the first radiating conductor layer. The first and second high frequency signals are respectively transmitted through the first and second signal paths. A first connection conductor is connected to the first and second signal paths, and positioned on a negative side of the Z-axis of the second radiating conductor layer.

This application claims the benefit of priority to Japanese Patent Application No. 2023-000530 filed on Jan. 5, 2023 and is a Continuation Application of PCT Application No. PCT/JP2023/043757 filed on Dec. 7, 2023. The entire contents of each application are hereby incorporated herein by reference.

### BACKGROUND OF THE INVENTION

### 1. Field of the Invention

The present invention relates to multilayer substrates each including multiple radiating conductor layers.

### 2. Description of the Related Art

As an example of a conventional multilayer substrate, a multilayer patch antenna described in Japanese Unexamined Patent Application Publication No. 2022-502909 has been known. This multilayer patch antenna includes a parasitic patch radiator that radiates high frequency signals in two orthogonal polarizations.

There is a demand for the multilayer patch antenna described in Japanese Unexamined Patent Application Publication No. 2022-502909 to improve isolation between the high frequency signals in two orthogonal polarizations.

### SUMMARY OF THE INVENTION

Example embodiments of the present invention provide multilayer substrates and wiring substrates that each improve isolation between a first high frequency signal and a second high frequency signal.

A multilayer substrate according to an example embodiment of the present invention includes a multilayer body, a first radiating conductor layer, a second radiating conductor layer, a first signal path, a second signal path, and a first connection conductor. The multilayer body includes a plurality of insulator layers laminated along a Z-axis. The first radiating conductor layer is provided on the multilayer body to receive or radiate a first high frequency signal and a second high frequency signal. A vibration direction of an electromagnetic field by the second high frequency signal propagating through air is different from a vibration direction of an electromagnetic field by the first high frequency signal propagating through the air. The second radiating conductor layer is provided in or on the multilayer body, positioned on a negative side of the Z-axis of the first radiating conductor layer, and overlaps with the first radiating conductor layer when viewed in a negative direction of the Z-axis. The first signal path and the second signal path are connected to the first radiating conductor layer. The first high frequency signal is transmitted through the first signal path. The second high frequency signal is transmitted through the second signal path. The first connection conductor is provided in or on the multilayer body, connected to the first signal path and the second signal path, and positioned on the negative side of the Z-axis of the second radiating conductor layer.

A multilayer substrate according to another example embodiment of the present invention includes a multilayer body, a first radiating conductor layer, a second radiating conductor layer, a first signal path, a second signal path, and a first connection conductor. The multilayer body includes a plurality of insulator layers laminated along a Z-axis. The first radiating conductor layer is provided in or on the multilayer body. The first radiating conductor layer includes a first feed point and a second feed point. When viewed in a negative direction of the Z-axis, the second feed point does not have a point-symmetric relationship with the first feed point with respect to a center of gravity of a figure defined by an outer edge of the first radiating conductor layer. The second radiating conductor layer is provided in or on the multilayer body, positioned on a negative side of the Z-axis of the first radiating conductor layer, and overlaps with the first radiating conductor layer when viewed in the negative direction of the Z-axis. The first signal path and the second signal path are connected to the first radiating conductor layer. The first connection conductor is provided on the multilayer body, connected to the first signal path and the second signal path, and positioned on the negative side of the Z-axis of the second radiating conductor layer.

A wiring substrate according to another example embodiment of the present invention includes, a first multilayer body, a first signal path portion, a second signal path portion, and a first connection conductor. An antenna component is provided in or on the first multilayer body, and positioned on a positive side of a Z-axis of the first multilayer body. The antenna component includes a second multilayer body, a first radiating conductor layer, and a second radiating conductor layer. The first multilayer body includes a plurality of insulator layers laminated along the Z-axis. The second multilayer body includes a plurality of insulator layers laminated along the Z-axis. The first radiating conductor layer is provided in or on the second multilayer body and receives or radiates a first high frequency signal and a second high frequency signal. A vibration direction of an electromagnetic field by the second high frequency signal propagating through air is different from a vibration direction of an electromagnetic field by the first high frequency signal propagating through the air. The second radiating conductor layer is provided in or on the second multilayer body, positioned on a negative side of the Z-axis of the first radiating conductor layer, and overlaps with the first radiating conductor layer when viewed in a negative direction of the Z-axis. The first signal path portion and the second signal path portion are provided in or on the first multilayer body and electrically connected to the first radiating conductor layer. The first high frequency signal is transmitted through the first signal path portion. The second high frequency signal is transmitted through the second signal path portion. The first connection conductor is provided in or on the second multilayer body, connected to the first signal path portion and the second signal path portion, and positioned on the negative side of the Z-axis of the second radiating conductor layer.

According to example embodiments of the present invention, it is possible to provide multilayer substrates and wiring substrates that each improve isolation between a first high frequency signal and a second high frequency signal.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a multilayer substrate 10 according to an example embodiment of the present invention.

FIG. 2 is a back view of the multilayer substrate 10 according to an example embodiment of the present invention in use.

FIG. 3 is an exploded perspective view of a multilayer substrate 10a according to an example embodiment of the present invention.

FIG. 4 is an exploded perspective view of a multilayer substrate 10b according to an example embodiment of the present invention.

### DETAILED DESCRIPTION OF THE EXAMPLE EMBODIMENTS

Example embodiments of the present invention will be described in detail below with reference to the drawings.

### EXAMPLE EMBODIMENT

### Structure of Multilayer Substrate 10

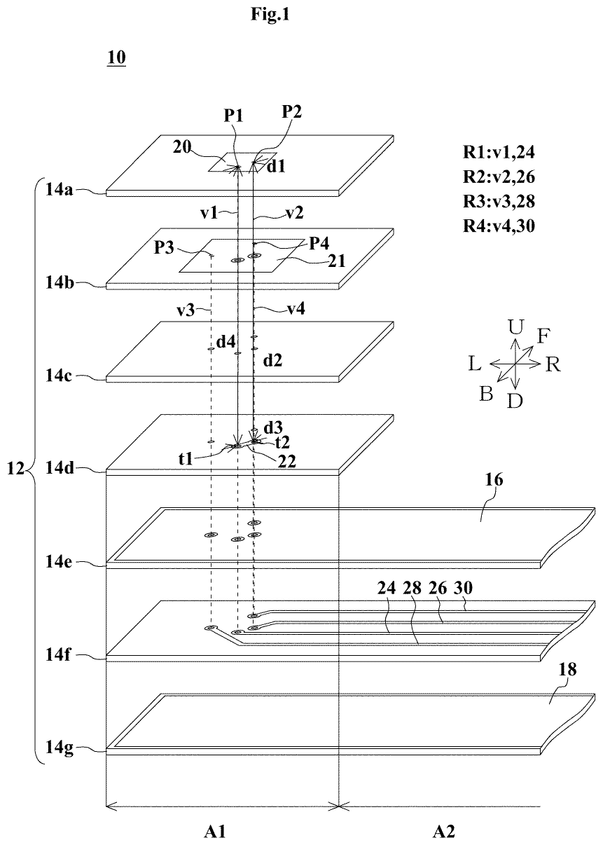

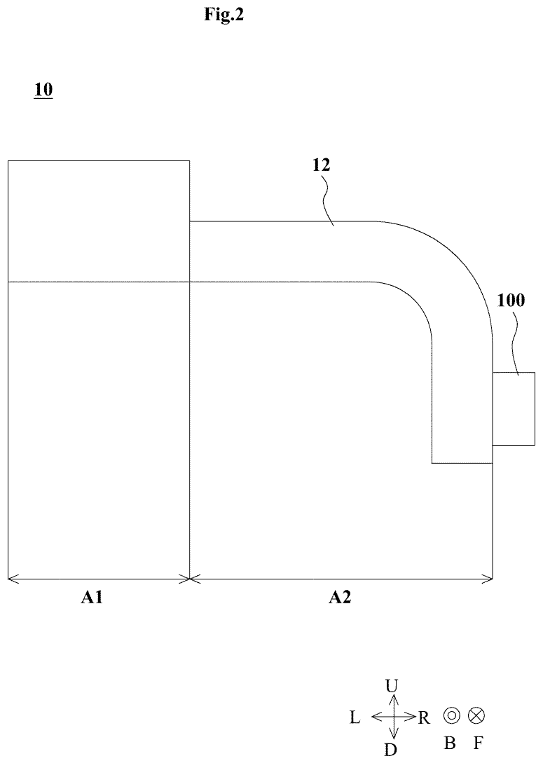

A structure of a multilayer substrate 10 according to an example embodiment of the present invention is described below with reference to the drawings. FIG. 1 is an exploded perspective view of the multilayer substrate 10. FIG. 2 is a back view of the multilayer substrate 10 in use.

Hereinafter, a laminating direction of a multilayer body 12 of the multilayer substrate 10 is defined as a vertical direction. A vertical axis coincides with a Z-axis. An upward direction is a positive direction of the Z-axis. A downward direction is a negative direction of the Z-axis. While the multilayer body 12 is viewed in the downward direction, two axes along which sides of the multilayer body 12 extend are defined as a horizontal axis and a front and back axis, respectively. The horizontal axis is orthogonal or substantially orthogonal to the vertical axis. The front and back axis is orthogonal or substantially orthogonal to the vertical axis and the horizontal axis. The definition of the direction in the present specification is an example. Accordingly, the direction in actual use of the multilayer substrate direction in the present specification do not need to coincide with each other.

Hereinafter, X is a component or a member of the multilayer substrate 10. In the present specification, each portion of X is defined as follows unless otherwise stated. A front portion of X means a front half of X. A back portion of X means a back half of X. A left portion of X means a left half of X. A right portion of X means a right half of X. An upper portion of X means an upper half of X. A lower portion of X means a lower half of X. A front end of X means an end of X in a front direction. A back end of X means an end of X in a back direction. A left end of X means an end of X in a left direction. A right end of X means an end of X in a right direction. An upper end of X means an end of X in the upward direction. A lower end of X means an end of X in the downward direction. A front end portion of X means the front end of X and the vicinity thereof. A back end portion of X means the back end of X and the vicinity thereof. A left end portion of X means the left end of X and the vicinity thereof. A right end portion of X means the right end of X and the vicinity thereof. An upper end portion of X means the upper end of X and the vicinity thereof. A lower end portion of X means the lower end of X and the vicinity thereof.

The multilayer substrate 10 is used as an antenna and a transmission line. The multilayer substrate 10 is, for example, electrically connected to a circuit substrate. As illustrated in FIG. 1, the multilayer substrate 10 includes the multilayer body 12, a first ground conductor layer 16, a second ground conductor layer 18, a first radiating conductor layer 20, a second radiating conductor layer 21, a first connection conductor 22, a first signal path R1, and a second signal path R2.

The multilayer body 12 has a plate shape. As illustrated in FIG. 1 and FIG. 2, the multilayer body 12 has a strip shape extending along the horizontal axis when viewed in the downward direction. The multilayer body 12 includes insulator layers 14a to 14g that are laminated along the vertical axis (the Z-axis). The insulator layers 14a to 14g are arranged from top to bottom in this order.

The insulator layers 14e to 14g have a strip shape extending along the horizontal axis when viewed in the downward direction. The insulator layers 14a to 14d have a rectangular or substantially rectangular shape when viewed in the downward direction. Accordingly, a length of the insulator layers 14e to 14g in the horizontal axis is longer than a length of the insulator layers 14a to 14d in the horizontal axis. The insulator layers 14a to 14d overlap with left end portions of the insulator layers 14e to 14g when viewed in the downward direction. Material of the insulator layers 14a to 14g is, for example, thermoplastic resin such as polyimide and liquid crystal polymer. Accordingly, the multilayer body 12 has flexibility. Additionally, the insulator layers 14a to 14g are fused to each other between vertically adjacent layers.

The first radiating conductor layer 20 radiates a first high frequency signal and also radiates a second high frequency signal. The first radiating conductor layer 20 is provided in or on the multilayer body 12. In the present example embodiment, the first radiating conductor layer 20 is positioned on an upper main surface of the insulator layer 14a. As illustrated in FIG. 1, the first radiating conductor layer 20 has a square or substantially square shape including sides extending along the front and back axis and the horizontal axis when viewed in the downward direction. A length of one side of the first radiating conductor layer 20 is about one-half of a wavelength within a resonant frequency band of the first radiating conductor layer 20. A wavelength of the first high frequency signal and the second high frequency signal belong to the band of resonant frequency of the first radiating conductor layer 20. A resonant mode of the first radiating conductor layer 20 is a ground mode.

The second radiating conductor layer 21 radiates a third high frequency signal and also radiates a fourth high frequency signal. The second radiating conductor layer 21 is provided in or on the multilayer body 12. In the present example embodiment, the second radiating conductor layer 21 is positioned on an upper main surface of the insulator layer 14b. Thus, the second radiating conductor layer 21 is positioned below (a negative side of the Z-axis) the first radiating conductor layer 20.

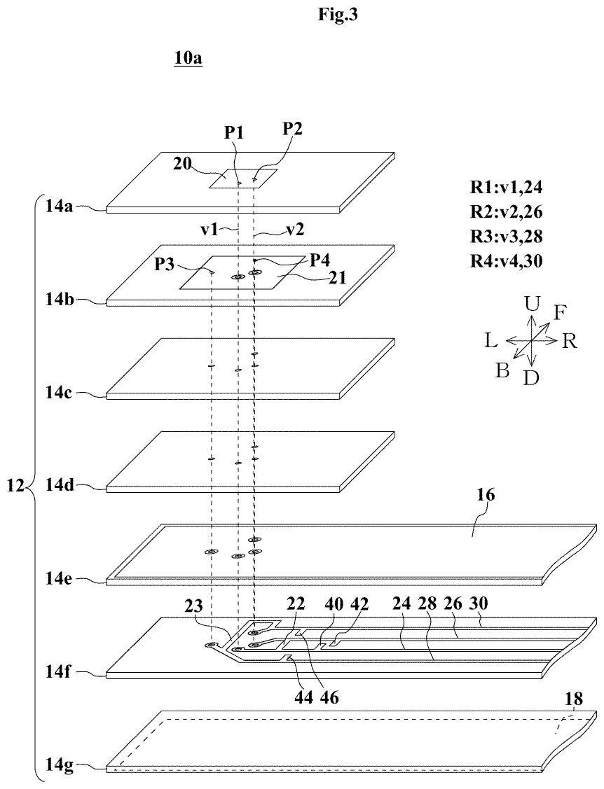

In addition, as illustrated in FIG. 3, the second radiating conductor layer 21 overlaps with the first radiating conductor layer 20 when viewed in the downward direction (the negative direction of the Z-axis). The second radiating conductor layer 21 has a square or substantially square shape including sides extending along the front and back axis and the horizontal axis when viewed in the downward direction. An area of the second radiating conductor layer 21 is greater than an area of the first radiating conductor layer 20. Accordingly, four sides of the second radiating conductor layer 21 do not overlap with the first radiating conductor layer 20 when viewed in the downward direction. The first radiating conductor layer 20 viewed in the downward direction is within an outer edge of the second radiating conductor layer 21. In addition, an intersection point of diagonal lines of the second radiating conductor layer 21 coincides with an intersection point of diagonal lines of the first radiating conductor layer 20 when viewed in the downward direction. That is, the center of gravity of a figure defined by the outer edge of the second radiating conductor layer 21 coincides with the center of gravity of a figure defined by the outer edge of the first radiating conductor layer 20 when viewed in the downward direction (the negative direction of the Z-axis).

A band of resonant frequency of the second radiating conductor layer 21 is lower than the band of resonant frequency of the first radiating conductor layer 20. In the present example embodiment, a difference between the band of resonant frequency of the first radiating conductor layer 20 and the band of resonant frequency of the second radiating conductor layer 21 is, for example, about 10% or more of a frequency of the first high frequency signal and a frequency of the second high frequency signal. The difference between the band of resonant frequency of the first radiating conductor layer 20 and the band of resonant frequency of the second radiating conductor layer 21 may be, for example, smaller than about 10% of the frequency of the first high frequency signal and the frequency of the second high frequency signal.

The first signal path R1 is connected to the first radiating conductor layer 20. The first signal path R1 includes a first signal conductor layer 24 and an interlayer connection conductor v1. The first signal conductor layer 24 is positioned on an upper main surface of the insulator layer 14f. The first signal conductor layer 24 has a linear shape extending along the horizontal axis when viewed in the downward direction. A left end portion of the first signal conductor layer 24 overlaps with the first radiating conductor layer 20 when viewed in the downward direction. The interlayer connection conductor v1 penetrates through the insulator layers 14a to 14e along the vertical axis. An upper end portion of the interlayer connection conductor v1 is connected behind the intersection point of the diagonal lines of the first radiating conductor layer 20. A lower end portion of the interlayer connection conductor v1 is connected to the left end portion of the first signal conductor layer 24.

The first high frequency signal is transmitted through the first signal path R1. Therefore, the first high frequency signal is supplied to the first radiating conductor layer 20 via the interlayer connection conductor v1. The interlayer connection conductor v1 is connected behind the intersection point of the diagonal lines of the first radiating conductor layer 20. Hereinafter, a point at which the interlayer connection conductor v1 is connected to the first radiating conductor layer 20 is referred to as a first feed point P1. The first high frequency signal resonates in the first radiating conductor layer 20 such that a current flows in the direction along the front and back axis.

The second signal path R2 is connected to the first radiating conductor layer 20. The second signal path R2 includes a second signal conductor layer 26 and an interlayer connection conductor v2. The second signal conductor layer 26 is positioned on the upper main surface of the insulator layer 14f. The second signal conductor layer 26 has a linear shape extending along the horizontal axis when viewed in the downward direction. A left end portion of the second signal conductor layer 26 overlaps with the first radiating conductor layer 20 when viewed in the downward direction. The interlayer connection conductor v2 penetrates through the insulator layers 14a to 14e along the vertical axis. An upper end portion of the interlayer connection conductor v2 is connected to the right of the intersection point of the diagonal lines of the first radiating conductor layer 20. Hereinafter, a point at which the interlayer connection conductor v2 is connected to the first radiating conductor layer 20 is referred to as a second feed point P2. Thus, the first radiating conductor layer 20 includes first feed point P1 and the second feed point P2. In addition, the second feed point P2 has no point-symmetric relationship with the first feed point P1 with respect to the center of gravity of the figure defined by the outer edge of the first radiating conductor layer 20 when viewed in the downward direction (the negative direction of the Z-axis). In the present example embodiment, the second feed point P2 has no point-symmetrical relationship with the first feed point P1 with respect to the intersection point of the diagonal lines of the first radiating conductor layer 20. A lower end portion of the interlayer connection conductor v2 is connected to the left end portion of the second signal conductor layer 26.

The second high frequency signal is transmitted through the second signal path R2. Therefore, the second high frequency signal is supplied to the first radiating conductor layer 20 via the interlayer connection conductor v2. The interlayer connection conductor v2 is connected to the right of the intersection point of the diagonal lines of the first radiating conductor layer 20. The second high frequency signal resonates in the first radiating conductor layer 20 such that the current flows in the direction along the horizontal axis. Therefore, a vibration direction of an electromagnetic field by the second high frequency signal propagating through the air is different from a vibration direction of an electromagnetic field by the first high frequency signal propagating through the air. In the present example embodiment, the vibration direction of the electromagnetic field by the second high frequency signal propagating through the air is orthogonal or substantially orthogonal to the vibration direction of the electromagnetic field by the first high frequency signal propagating through the air.

A third signal path R3 is connected to the second radiating conductor layer 21. The third signal path R3 includes a third signal conductor layer 28 and an interlayer connection conductor v3. The third signal conductor layer 28 is positioned on the upper main surface of the insulator layer 14f. The third signal conductor layer 28 has a linear shape extending along the horizontal axis when viewed in the downward direction. A left end portion of the third signal conductor layer 28 overlaps with the second radiating conductor layer 21 when viewed in the downward direction. The interlayer connection conductor v3 penetrates through the insulator layers 14a to 14e along the vertical axis. An upper end portion of the interlayer connection conductor v3 is connected to the left of the intersection point of the diagonal lines of the second radiating conductor layer 21. Hereinafter, a point at which the interlayer connection conductor v3 is connected to the second radiating conductor layer 21 is referred to as a third feed point P3. A lower end portion of the interlayer connection conductor v3 is connected to the left end portion of the third signal conductor layer 28.

The third high frequency signal is transmitted through the third signal path R3. Therefore, the third high frequency signal is supplied to the second radiating conductor layer 21 via the interlayer connection conductor v3. The interlayer connection conductor v3 is connected to the left of the intersection point of the diagonal lines of the second radiating conductor layer 21. Therefore, the third high frequency signal resonates in the second radiating conductor layer 21 such that the current flows in the direction along the horizontal axis.

A fourth signal path R4 is connected to the second radiating conductor layer 21. The fourth signal path R4 includes a fourth signal conductor layer 30 and an interlayer connection conductor v4. The fourth signal conductor layer 30 is positioned on the upper main surface of the insulator layer 14f. The fourth signal conductor layer 30 has a linear shape extending along the horizontal axis when viewed in the downward direction. A left end portion of the fourth signal conductor layer 30 overlaps with the second radiating conductor layer 21 when viewed in the downward direction. The interlayer connection conductor v4 penetrates through the insulator layers 14a to 14e along the vertical axis. An upper end portion of the interlayer connection conductor v4 is connected in front of the intersection point of the diagonal lines of the second radiating conductor layer 21. Hereinafter, a point at which the interlayer connection conductor v4 is connected to the second radiating conductor layer 21 is referred to as a fourth feed point P4. The fourth feed point P4 has a point-symmetric relationship with the third feed point P3 with respect to the intersection point of the diagonal lines of the second radiating conductor layer 21. A lower end portion of the interlayer connection conductor v4 is connected to the left end portion of the fourth signal conductor layer 30.

The fourth high frequency signal is transmitted through the fourth signal path R4. Therefore, the fourth high frequency signal is supplied to the second radiating conductor layer 21 via the interlayer connection conductor v4. The interlayer connection conductor v4 is connected in front of the intersection point of the diagonal lines of the second radiating conductor layer 21. The fourth high frequency signal resonates in the second radiating conductor layer 21 such that the current flows in the direction along the front and back axis. Therefore, a vibration direction of an electromagnetic field by the fourth high frequency signal propagating through the air is different from a vibration direction of an electromagnetic field by the third high frequency signal propagating through the air. In the present example embodiment, the vibration direction of the electromagnetic field by the fourth high frequency signal propagating through the air is orthogonal or substantially orthogonal to the vibration direction of the electromagnetic field by the third high frequency signal propagating through the air.

The first ground conductor layer 16 is provided to the multilayer body 12. In the present example embodiment, the first ground conductor layer 16 is positioned on an upper main surface of the insulator layer 14e. Thus, the first ground conductor layer 16 is positioned below (the negative side of the Z-axis) the second radiating conductor layer 21. The first ground conductor layer 16 is positioned above the first signal conductor layer 24, the second and the fourth signal conductor layer 30.

The first ground conductor layer 16 covers an entire or substantially an entire surface of the upper main surface of the insulator layer 14e. Thus, the first ground conductor layer 16 overlaps with the first radiating conductor layer 20 and the second radiating conductor layer 21 when viewed in the downward direction (the negative direction of the Z-axis). Accordingly, the first radiating conductor layer 20, the second radiating conductor layer 21, and the first ground conductor layer 16 define and function as a patch antenna. Additionally, the first ground conductor layer 16 overlaps with the first signal conductor layer 24, the second signal conductor layer 26, the third signal conductor layer 28, and the fourth signal conductor layer 30 when viewed in the downward direction.

The second ground conductor layer 18 is provided in or on the multilayer body 12. In the present example embodiment, the second ground conductor layer 18 is positioned on an upper main surface of the insulator layer 14g. Thus, The second ground conductor layer 18 is positioned below (the negative side of the Z-axis) the first ground conductor layer 16. The second ground conductor layer 18 is positioned below the first signal conductor layer 24, the second signal conductor layer 26, the third signal conductor layer 28, and the fourth signal conductor layer 30.

The second ground conductor layer 18 covers an entire or substantially an entire surface of the upper main surface of the insulator layer 14g. Thus, the second ground conductor layer 18 overlaps with the first ground conductor layer 16 when viewed in the downward direction (the negative direction of the Z-axis). Additionally, the second ground conductor layer 18 overlaps with the first signal conductor layer 24, the second signal conductor layer 26, the third signal conductor layer 28, and the fourth signal conductor layer 30 when viewed in the downward direction (the negative direction of the Z-axis). The first ground conductor layer 16 and the second ground conductor layer 18 are connected to a ground potential. Thus, the first signal conductor layer 24, the second signal conductor layer 26, the third signal conductor layer 28, the fourth signal conductor layer 30, the first ground conductor layer 16, and the second ground conductor layer 18 have a stripline structure.

The first connection conductor 22 is provided in or on the multilayer body 12. In the present example embodiment, the first connection conductor 22 is a conductor layer positioned on an upper main surface of the insulator layer 14d. Accordingly, the first connection conductor 22 is positioned below (the negative side of the Z-axis) the second radiating conductor layer 21 and positioned above (a positive side of the Z-axis) the first ground conductor layer 16. In addition, a distance from the first connection conductor 22 to the first ground conductor layer 16 in the vertical axis (the Z-axis) is shorter than a distance from the first connection conductor 22 to the second radiating conductor layer 21 in the vertical axis (the Z-axis). Additionally, the first connection conductor 22 overlaps with the second radiating conductor layer 21 when viewed in the downward direction.

The thus described first connection conductor 22 is connected to the first signal path R1 and the second signal path R2. In the present example embodiment, the first connection conductor 22 has a linear shape including a first end portion t1 and a second end portion t2 when viewed in the downward direction. The first end portion t1 of the first connection conductor 22 is connected to the interlayer connection conductor v1. The second end portion t2 of the first connection conductor 22 is connected to the interlayer connection conductor v2.

The multilayer substrate 10 is designed to satisfy the following conditions. A phase difference between the first high frequency signal that is inputted to the interlayer connection conductor v2 in the first radiating conductor layer 20 and the first high frequency signal that is inputted to the interlayer connection conductor v2 via the first connection conductor 22 is, for example, an odd multiple of about 180°. It may be a phase state in which the first high frequency signal that is inputted to the interlayer connection conductor v2 without the first connection conductor 22 within the band used is attenuated by the first high frequency signal that is inputted to the interlayer connection conductor v2 via the first connection conductor 22. Additionally, a phase difference between the second high frequency signal that is inputted to the interlayer connection conductor v1 in the first radiating conductor layer 20 and the second high frequency signal that is inputted to the interlayer connection conductor v1 via the first connection conductor 22 is, for example, an odd multiple of about 180°. It may be a phase state in which the second high frequency signal that is inputted to the interlayer connection conductor v1 without the first connection conductor 22 within the band used is attenuated by the second high frequency signal that is inputted to the interlayer connection conductor v1 via the first connection conductor 22.

The first ground conductor layer 16, the second ground conductor layer 18, the first radiating conductor layer 20, the second radiating conductor layer 21, the first signal conductor layer 24, the second signal conductor layer 26, the third signal conductor layer 28, and the fourth signal conductor layer 30 are, for example, formed by applying patterning to metallic foil pasted on upper main surfaces of the insulator layers 14a to 14g. The metal is, for example, copper. Additionally, the interlayer connection conductors v1 to v4 are, for example, via hole conductors. The via hole conductors are formed by, for example, forming through-holes in the insulator layers 14a to 14e, filling the through-holes with conductive paste, and sintering the conductive paste.

Next, a usage example of the multilayer substrate 10 is described. As illustrated in FIG. 1, the multilayer substrate 10 includes a first section A1 and a second section A2. The first section A1 includes the first radiating conductor layer 20 and the second radiating conductor layer 21. The second section A2 does not include the first radiating conductor layer 20 and the second radiating conductor layer 21. A vertical thickness of the first section A1 is greater than a vertical thickness of the second section A2. Accordingly, the second section A2 is easily bent in the upward direction or the downward direction more than the first section A1.

Therefore, in the multilayer substrate 10, the second section A2 is bent as illustrated in FIG. 2. Additionally, a connector 100 is provided at an end portion of the second section A2. The connector 100 is coupled to a connector provided to a not-illustrated circuit substrate. The multilayer substrate 10 may be connected to another circuit substrate without the connector 100.

### Advantageous Effects

According to the multilayer substrate 10, it is possible to improve isolation between the first high frequency signal and the second high frequency signal. To be more specific, in the first feed point P1 and the second feed point P2 of the first connection conductor 22, when the first high frequency signal enters the interlayer connection conductor v2 from the first feed point P1 via the second feed point P2, the first high frequency signal becomes noise.

Therefore, the first connection conductor 22 is connected to the first signal path R1 and the second signal path R2. The phase difference occurs between the first high frequency signal that is inputted to the interlayer connection conductor v2 in the first radiating conductor layer 20 and the first high frequency signal that is inputted to the interlayer connection conductor v2 via the first connection conductor 22. Thus, the first high frequency signal that is inputted to the interlayer connection conductor v2 in the first radiating conductor layer 20 and the first high frequency signal that is inputted to the interlayer connection conductor v2 via the first connection conductor 22 cancel each other. As a result, the first high frequency signal is reduced or prevented from becoming noise. With the same reason, the second high frequency signal is reduced or prevented from becoming noise.

Here, the first connection conductor 22 is designed so as to be able to reduce or prevent the first high frequency signal that enters the interlayer connection conductor v2 from the second feed point P2 from becoming noise. Similarly, the first connection conductor 22 is designed so as to be able to reduce or prevent the second high frequency signal that enters the interlayer connection conductor v1 from the first feed point P1 from becoming noise. Specifically, the phase difference between the first high frequency signal that is inputted to the interlayer connection conductor v2 in the first radiating conductor layer 20 and the first high frequency signal that is inputted to the interlayer connection conductor v2 via the first connection conductor 22 is, for example, an odd multiple of about 180°. It may be the phase state in which the first high frequency signal that is inputted to the interlayer connection conductor v2 without the first connection conductor 22 within the band used is attenuated by the first high frequency signal that is inputted to the interlayer connection conductor v2 via the first connection conductor 22. Additionally, the phase difference between the second high frequency signal that is inputted to the interlayer connection conductor v1 in the first radiating conductor layer 20 and the second high frequency signal that is inputted to the interlayer connection conductor v1 via the first connection conductor 22 is, for example, an odd multiple of about 180°. It may be a phase state in which the second high frequency signal that is inputted to the interlayer connection conductor v1 without the first connection conductor 22 within the band used is attenuated by the second high frequency signal that is inputted to the interlayer connection conductor v1 via the first connection conductor 22.

In the multilayer substrate 10, the first connection conductor 22 is positioned below (the negative side of the Z-axis) the second radiating conductor layer 21. Thus, the second radiating conductor layer 21 is positioned between the first radiating conductor layer 20 and the first connection conductor 22. Therefore, the electromagnetic field generated from the first radiating conductor layer 20 is reduced or prevented from reaching the first connection conductor 22 and becoming noise.

In the multilayer substrate 10, the first ground conductor layer 16 is positioned between the first connection conductor 22 and the first signal conductor layer 24, the second and the fourth signal conductor layer 30. Thus, noise entering of the first connection conductor 22 and the first signal conductor layer 24, the second signal conductor layer 26, the third signal conductor layer 28, and the fourth signal conductor layer 30 is reduced or prevented.

### First Modification

Next, a multilayer substrate 10a according to a first modification of an example embodiment of the present invention is described with reference to the drawing. FIG. 3 is an exploded perspective view of the multilayer substrate 10a.

The multilayer substrate 10a is different from the multilayer substrate 10 in the following points.
The first connection conductor 22 is positioned below (the negative side of the Z-axis) the first ground conductor layer 16 and positioned above (the positive side of the Z-axis) the second ground conductor layer 18.
The multilayer substrate 10a further includes a second connection conductor 23.
The first signal path R1 includes a first branch conductor layer 40.
The second signal path R2 includes a second branch conductor layer 42.
The third signal path R3 includes a third branch conductor layer 44.
The fourth signal path R4 includes a fourth branch conductor layer 46.

The first connection conductor 22 is positioned below (the negative side of the Z-axis) the first ground conductor layer 16 and positioned above (the positive side of the Z-axis) the second ground conductor layer 18. In the present example embodiment, the first connection conductor 22 is a conductor layer positioned on the upper main surface of the insulator layer 14f. In addition, the first connection conductor 22 is connected to the first signal conductor layer 24 and the second signal conductor layer 26.

The second connection conductor 23 is provided in or on the multilayer body 12. The second connection conductor 23 is positioned below (the negative side of the Z-axis) the first ground conductor layer 16 and positioned above the second ground conductor layer 18. In the present example embodiment, the second connection conductor 23 is a conductor layer positioned on the upper main surface of the insulator layer 14f. The second connection conductor 23 is connected to the third signal path R3 and the fourth signal path R4. In the present example embodiment, the second connection conductor 23 is connected to the third signal conductor layer 28 and the fourth signal conductor layer 30.

The first signal path R1 includes the first branch conductor layer 40. In the present example embodiment, the first branch conductor layer 40 is connected to the first signal conductor layer 24. The first branch conductor layer 40 traps the third high frequency signal and the fourth high frequency signal. The first branch conductor layer 40 is, for example, an open stub. Accordingly, a length of the first branch conductor layer 40 is, for example, about one-quarter of a wavelength within the resonant frequency band of the second radiating conductor layer 21.

The second signal path R2 includes the second branch conductor layer 42. In the present example embodiment, second branch conductor layer 42 is connected to the second signal conductor layer 26. The second branch conductor layer 42 traps the third high frequency signal and the fourth high frequency signal. The second branch conductor layer 42 is, for example, an open stub. Accordingly, a length of the second branch conductor layer 42 is, for example, about one-quarter of the wavelength within the resonant frequency band of the second radiating conductor layer 21.

The third signal path R3 includes the third branch conductor layer 44. In the present example embodiment, the third branch conductor layer 44 is connected to the third signal conductor layer 28. The third branch conductor layer 44 traps the first high frequency signal and the second high frequency signal. The third branch conductor layer 44 is, for example, an open stub. Accordingly, a length of the third branch conductor layer 44 is, for example, about one-quarter of the wavelength in the band of resonant frequency of the first radiating conductor layer 20.

The fourth signal path R4 includes the fourth branch conductor layer 46. In the present example embodiment, the fourth branch conductor layer 46 is connected to the fourth signal conductor layer 30. The fourth branch conductor layer 46 traps the first high frequency signal and the second high frequency signal. The fourth branch conductor layer 46 is, for example, an open stub. Accordingly, a length of the fourth branch conductor layer 46 is, for example, about one-quarter of the wavelength within the resonant frequency band of the first radiating conductor layer 20. Other structures of the multilayer substrate 10a are the same or substantially the same as that of the multilayer substrate 10. For this reason, description thereof is omitted. The multilayer substrate 10a can achieve the same advantageous effects as the multilayer substrate 10.

According to the multilayer substrate 10a, with the first connection conductor 22 being provided, it is possible to improve isolation between the third high frequency signal and the fourth high frequency signal with the same reason of the improvement of isolation between the first high frequency signal and the second high frequency signal. The second connection conductor 23 is designed so as to be able to reduce or prevent the third high frequency signal that enters the interlayer connection conductor v4 from the fourth feed point P4 from becoming noise. Similarly, the second connection conductor 23 is designed so as to be able to reduce or prevent the fourth high frequency signal that enters the interlayer connection conductor v3 from the third feed point P3 from becoming noise. A method of designing the second connection conductor 23 is the same as or similar to a method of designing the first connection conductor 22. For this reason, description thereof is omitted.

According to the multilayer substrate 10a, the first connection conductor 22 is positioned below (the negative side of the Z-axis) the first ground conductor layer 16. Thus, the first ground conductor layer 16 is positioned between the first radiating conductor layer 20 and the second radiating conductor layer 21 and the first connection conductor 22. Therefore, the electromagnetic fields generated from the first radiating conductor layer 20 and the second radiating conductor layer 21 are reduced or prevented from reaching the first connection conductor 22 and becoming noise.

According to the multilayer substrate 10a, the second connection conductor 23 is positioned below (the negative side of the Z-axis) the first ground conductor layer 16. Thus, the first ground conductor layer 16 is positioned between the first radiating conductor layer 20 and the second radiating conductor layer 21 and the second connection conductor 23. Therefore, the electromagnetic fields generated from the first radiating conductor layer 20 and the second radiating conductor layer 21 are reduced or prevented from reaching the second connection conductor 23 and becoming noise.

In the multilayer substrate 10a, the first signal path R1 is provided with the first branch conductor layer 40. The first branch conductor layer 40 traps the third high frequency signal and the fourth high frequency signal. Thus, even when the third high frequency signal and the fourth high frequency signal radiated by the second radiating conductor layer 21 enter the first signal path R1, the first branch conductor layer 40 traps the third high frequency signal and the fourth high frequency signal. As a result, the third high frequency signal and the fourth high frequency signal are reduced or prevented from becoming noise in the first signal path R1.

In the multilayer substrate 10a, the second signal path R2 is provided with the second branch conductor layer 42. The second branch conductor layer 42 traps the third high frequency signal and the fourth high frequency signal. Thus, even when the third high frequency signal and the fourth high frequency signal radiated by the second radiating conductor layer 21 enter the second signal path R2, the second branch conductor layer 42 traps the third high frequency signal and the fourth high frequency signal. As a result, the third high frequency signal and the fourth high frequency signal are reduced or prevented from becoming noise in the second signal path R2.

In the multilayer substrate 10a, the third signal path R3 is provided with the third branch conductor layer 44. The third branch conductor layer 44 traps the first high frequency signal and the second high frequency signal. Thus, even when the first high frequency signal and the second high frequency signal radiated by the first radiating conductor layer 20 enter the third signal path R3, the third branch conductor layer 44 traps the first high frequency signal and the second high frequency signal. As a result, the first high frequency signal and the second high frequency signal are reduced or prevented from becoming noise in the third signal path R3.

In the multilayer substrate 10a, the fourth signal path R4 is provided with the fourth branch conductor layer 46. The fourth branch conductor layer 46 traps the first high frequency signal and the second high frequency signal. Thus, even when the first high frequency signal and the second high frequency signal radiated by the first radiating conductor layer 20 enter the fourth signal path R4, the fourth branch conductor layer 46 traps the first high frequency signal and the second high frequency signal. As a result, the first high frequency signal and the second high frequency signal are reduced or prevented from becoming noise in the fourth signal path R4.

### Second Modification

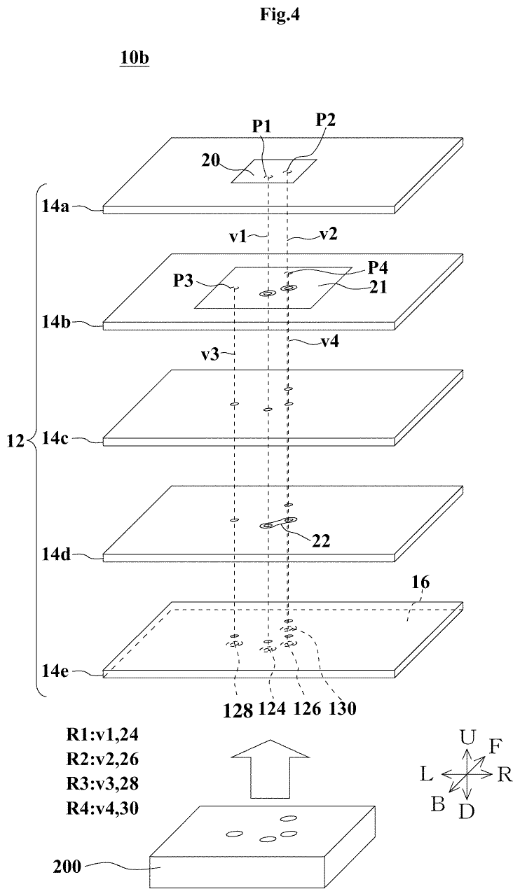

Next, a multilayer substrate 10b according to a second modification of an example embodiment of the present invention is described with reference to the drawing. FIG. 4 is an exploded perspective view of the multilayer substrate 10b.

The multilayer substrate 10b is different from the multilayer substrate 10 in the following points.
The first ground conductor layer 16 is positioned on a lower main surface of the insulator layer 14e.
The multilayer substrate 10b includes outer electrodes 124, 126, 128, and 130 instead of the first signal conductor layer 24, the second signal layer 26, the third signal conductor layer 28, and the fourth signal conductor layer 30.
An electronic component 200 is provided on a lower main surface of the multilayer body 12 of the multilayer substrate 10b.

The outer electrodes 124, 126, 128, and 130 are positioned on the lower main surface of the insulator layer 14e. The lower end portions of the interlayer connection conductors v1 to v4 are connected to the outer electrodes 124, 126, 128, and 130, respectively.

The electronic component 200 is, for example, a semiconductor integrated circuit. The electronic component 200 is provided on the outer electrodes 124, 126, 128, and 130 by soldering. Other structures of the multilayer substrate 10b are the same or substantially the same as that of the multilayer substrate 10. For this reason, description thereof is omitted. The multilayer substrate 10b can achieve the same or substantially the same advantageous effects as the multilayer substrate 10.

### Other Example Embodiments

Multilayer substrates according to example embodiments of the present invention are not limited to the multilayer substrates 10, 10a, and 10b and can be changed within the scope of the gist of the present invention. The configurations of the multilayer substrates 10, 10a, and 10b may be combined with each other appropriately.

The first radiating conductor layer 20 may receive the first high frequency signal and the second high frequency signal. The second radiating conductor layer 21 may receive the third high frequency signal and the fourth high frequency signal.

In the multilayer substrate 10a, the first branch conductor layer 40, the second branch conductor layer 42, the third branch conductor layer 44, and the fourth branch conductor layer 46 are not necessary features. The multilayer substrate 10a may include any one or any two or any three of the first branch conductor layer 40, the second branch conductor layer 42, the third branch conductor layer 44, and the fourth branch conductor layer 46.

The second connection conductor 23 is not a necessary feature.

The first branch conductor layer 40, the second branch conductor layer 42, the third branch conductor layer 44, and the fourth branch conductor layer 46 may be, for example, a short branch conductor layer, for example.

The first branch conductor layer 40, the second branch conductor layer 42, the third branch conductor layer 44, and the fourth branch conductor layer 46 may be provided for purpose of impedance matching, instead of for purpose of trapping the high frequency signal, for example.

The first connection conductor 22 and the second connection conductor 23 are not limited to the conductor layer. Accordingly, the first connection conductor 22 and the second connection conductor 23 may be, for example, an interlayer connection conductor.

The multilayer substrate 10a includes the single multilayer body 12. However, the multilayer substrate 10a may include multiple multilayer bodies. Specifically, the multilayer substrate 10a in FIG. 3 may include a first multilayer body and a second multilayer body. In this case, the first multilayer body includes the insulator layers 14a to 14d. Material of the insulator layers 14a to 14d is, for example, ceramic. The second multilayer body includes the insulator layers 14e to 14g. Material of the insulator layers 14e to 14g is, for example, thermoplastic resin.

An antenna component according to an example embodiment of the present invention includes the insulator layers 14a to 14d, the first radiating conductor layer 20, and the second radiating conductor layer 21. A wiring substrate according to an example embodiment of the present invention includes the insulator layers 14e to 14g, the first ground conductor layer 16, the second ground conductor layer 18, the first signal conductor layer 24, the second signal conductor layer 26, the third signal conductor layer 28, the fourth signal conductor layer 30, and a portion of the interlayer connection conductors v1 to v4. The antenna component is provided on the first multilayer body by soldering. In this case, the antenna component is positioned above (the positive side of the Z-axis) the first multilayer body.

A portion of the interlayer connection conductor v1 and the first signal conductor layer 24 are a first signal path portion. The first signal path portion is electrically connected to the first radiating conductor layer 20. A portion of the interlayer connection conductor v2 and the second signal conductor layer 26 are a second signal path portion. The second signal path portion is electrically connected to the first radiating conductor layer 20. A portion of the interlayer connection conductor v3 and the third signal conductor layer 28 are a third signal path portion. The third signal path portion is electrically connected to the second radiating conductor layer 21. A portion of the interlayer connection conductor v4 and the fourth signal conductor layer 30 are a fourth signal path portion. The fourth signal path portion is electrically connected to the second radiating conductor layer 21.

The multilayer substrate 10 includes the single multilayer body 12. However, as with the multilayer substrate 10a, the multilayer substrate 10 may include the first multilayer body and the second multilayer body. That is, the first radiating conductor layer 20 may be provided in or on the first multilayer body. The first connection conductor 22 may be provided in or on the second multilayer body. The second multilayer body is provided on the first multilayer body by soldering. Therefore, if the first connection conductor 22 is provided in or on the first multilayer body, a variation likely occurs in lengths of current paths from the first radiating conductor layer 20 to the first connection conductor 22. Therefore, the first connection conductor 22 is provided in or on the second multilayer body. Thus, the occurrence of the variations in the lengths of the current paths from the first radiating conductor layer 20 to the first connection conductor 22 is reduced or prevented.

The multilayer substrate 10 does not have to include a portion lower than the insulator layer 14d. In this case, the material of the insulator layers 14a to 14d may be according to an example embodiment of the present invention, ceramic.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate, comprising:
a multilayer body;
a first radiating conductor layer;
a second radiating conductor layer;
a first signal path;
a second signal path; and
a first connection conductor; wherein
the multilayer body includes a plurality of insulator layers laminated along a Z-axis;
the first radiating conductor layer is provided in or on the multilayer body to receive or radiate a first high frequency signal and a second high frequency signal;
a vibration direction of an electromagnetic field by the second high frequency signal propagating through air is different from a vibration direction of an electromagnetic field by the first high frequency signal propagating through the air;
the second radiating conductor layer is provided in or on the multilayer body, positioned on a negative side of the Z-axis of the first radiating conductor layer, and overlaps with the first radiating conductor layer when viewed in a negative direction of the Z-axis;
the first signal path and the second signal path are connected to the first radiating conductor layer;
the first high frequency signal is transmitted through the first signal path;
the second high frequency signal is transmitted through the second signal path; and
the first connection conductor is provided in or on the multilayer body, connected to the first signal path and the second signal path, and positioned on the negative side of the Z-axis of the second radiating conductor layer.

2. The multilayer substrate according to claim 1, further comprising:
a first ground conductor layer; wherein
the first ground conductor layer is provided in or on the multilayer body, positioned on the negative side of the Z-axis of the second radiating conductor layer, and overlaps with the first radiating conductor layer and the second radiating conductor layer when viewed in the negative direction of the Z-axis.

3. The multilayer substrate according to claim 2, wherein the first connection conductor is positioned on the negative side of the Z-axis of the second radiating conductor layer and on a positive side of the Z-axis of the first ground conductor layer.

4. The multilayer substrate according to claim 3, wherein a distance from the first connection conductor to the first ground conductor layer in the Z-axis is shorter than a distance from the first connection conductor to the second radiating conductor layer in the Z-axis.

5. The multilayer substrate according to claim 2, further comprising:
a second ground conductor layer; wherein
the second ground conductor layer is provided in or on the multilayer body, positioned on the negative side of the Z-axis of the first ground conductor layer, and overlaps with the first ground conductor layer when viewed in the negative direction of the Z-axis; and
the first connection conductor is positioned on the negative side of the Z-axis of the first ground conductor layer and on a positive side of the Z-axis of the second ground conductor layer.

6. The multilayer substrate according to claim 1, further comprising:
a third signal path; and
a fourth signal path; wherein
the second radiating conductor layer is configured to receive or radiate a third high frequency signal and a fourth high frequency signal;
a vibration direction of an electromagnetic field by the fourth high frequency signal propagating through the air is different from a vibration direction of an electromagnetic field by the third high frequency signal propagating through the air;
the third signal path and the fourth signal path are connected to the second radiating conductor layer;
the third high frequency signal is transmitted through the third signal path; and
the fourth high frequency signal is transmitted through the fourth signal path.

7. The multilayer substrate according to claim 6, further comprising:
a second connection conductor; wherein
the second connection conductor is provided in or on the multilayer body and connected to the third signal path and the fourth signal path.

8. The multilayer substrate according to claim 1, further comprising:
a second connection conductor; and
a first ground conductor layer; wherein
the first ground conductor layer is provided in or on the multilayer body, positioned on the negative side of the Z-axis of the second radiating conductor layer, and overlaps with the first radiating conductor layer and the second radiating conductor layer when viewed in the negative direction of the Z-axis; and
the second connection conductor is positioned on the negative side of the Z-axis of the first ground conductor layer.

9. The multilayer substrate according to claim 1, wherein a resonant frequency of the second radiating conductor layer is lower than a resonant frequency of the first radiating conductor layer.

10. The multilayer substrate according to claim 9, wherein a difference between a band of the resonant frequency of the first radiating conductor layer and a band of the resonant frequency of the second radiating conductor layer is about 10% or more of a frequency of the first high frequency signal and a frequency of the second high frequency signal.

11. The multilayer substrate according to claim 6, wherein
the first signal path includes a first branch conductor layer; and
the second signal path includes a second branch conductor layer.

12. The multilayer substrate according to claim 6, wherein
the third signal path includes a third branch conductor layer; and
the fourth signal path includes a fourth branch conductor layer.

13. A multilayer substrate, comprising:
a multilayer body;
a first radiating conductor layer;
a second radiating conductor layer;
a first signal path;
a second signal path; and
a first connection conductor; wherein
the multilayer body includes a plurality of insulator layers laminated along a Z-axis;
the first radiating conductor layer is provided in or on the multilayer body;
the first radiating conductor layer includes a first feed point and a second feed point;
when viewed in a negative direction of the Z-axis, the second feed point does not have a point-symmetric relationship with the first feed point with respect to a center of gravity of a figure defined by an outer edge of the first radiating conductor layer;
the second radiating conductor layer is provided in or on the multilayer body, positioned on a negative side of the Z-axis of the first radiating conductor layer, and overlaps with the first radiating conductor layer when viewed in the negative direction of the Z-axis;
the first signal path and the second signal path are connected to the first radiating conductor layer; and
the first connection conductor is provided in or on the multilayer body, connected to the first signal path and the second signal path at only one point, and positioned on the negative side of the Z-axis of the second radiating conductor layer.

14. The multilayer substrate according to claim 13, further comprising:
a first ground conductor layer; wherein
the first ground conductor layer is provided in or on the multilayer body, positioned on the negative side of the Z-axis of the second radiating conductor layer, and overlaps with the first radiating conductor layer and the second radiating conductor layer when viewed in the negative direction of the Z-axis.

15. The multilayer substrate according to claim 14, wherein the first connection conductor is positioned on the negative side of the Z-axis of the second radiating conductor layer and on a positive side of the Z-axis of the first ground conductor layer.

16. The multilayer substrate according to claim 15, wherein a distance from the first connection conductor to the first ground conductor layer in the Z-axis is shorter than a distance from the first connection conductor to the second radiating conductor layer in the Z-axis.

17. The multilayer substrate according to claim 14, further comprising:
a second ground conductor layer; wherein
the second ground conductor layer is provided in or on the multilayer body, positioned on the negative side of the Z-axis of the first ground conductor layer, and overlaps with the first ground conductor layer when viewed in the negative direction of the Z-axis; and
the first connection conductor is positioned on the negative side of the Z-axis of the first ground conductor layer and on a positive side of the Z-axis of the second ground conductor layer.

18. The multilayer substrate according to claim 13, wherein a resonant frequency of the second radiating conductor layer is lower than a resonant frequency of the first radiating conductor layer.

19. The multilayer substrate according to claim 18, wherein a difference between a band of the resonant frequency of the first radiating conductor layer and a band of the resonant frequency of the second radiating conductor layer is about 10% or more of a frequency of the first high frequency signal and a frequency of the second high frequency signal.

20. A wiring substrate, comprising:
a first multilayer body;
a first signal path portion;
a second signal path portion; and
a first connection conductor; wherein
an antenna component is provided on the first multilayer body;
the antenna component is positioned on a positive side of a Z-axis of the first multilayer body;
the antenna component includes a second multilayer body, a first radiating conductor layer, and a second radiating conductor layer;
the first multilayer body includes a plurality of insulator layers laminated along the Z-axis;
the second multilayer body includes a plurality of insulator layers laminated along the Z-axis;
the first radiating conductor layer is provided in or on the second multilayer body to receive or radiate a first high frequency signal and a second high frequency signal;
a vibration direction of an electromagnetic field by the second high frequency signal propagating through air is different from a vibration direction of an electromagnetic field by the first high frequency signal propagating through the air;
the second radiating conductor layer is provided in or on the second multilayer body, positioned on a negative side of the Z-axis of the first radiating conductor layer, and overlaps with the first radiating conductor layer when viewed in a negative direction of the Z-axis;
the first signal path portion and the second signal path portion are provided in or on the first multilayer body and electrically connected to the first radiating conductor layer;
the first high frequency signal is transmitted through the first signal path portion;
the second high frequency signal is transmitted through the second signal path portion; and
the first connection conductor is provided in or on the second multilayer body, connected to the first signal path portion and the second signal path portion, and positioned on the negative side of the Z-axis of the second radiating conductor layer.
